(19) United States
(12) Patent Application Publication
(10) Pub. No.: US 2015/0372591 A1
(43) Pub. Date: Dec. 24, 2015

(54) POSITIVE AND NEGATIVE POTENTIAL GENERATING CIRCUIT

(71) Applicant: KABUSHIKI KAISHA TOSHIBA, Tokyo (JP)

(72) Inventor: Toshiki SESHITA, Kawasaki Kanagawa (JP)

(21) Appl. No.: 14/634,700

(22) Filed: Feb. 27, 2015

(30) Foreign Application Priority Data
Jun. 23, 2014 (JP) 2014-128594

(51) Int. Cl. H02M 3/07; H03K 5/08; H03K 3/03

(52) U.S. Cl. CPC H02M 3/07; H03K 3/0315; H03K 5/08

(57) ABSTRACT

A potential generating circuit of includes a charge pump having a first node at which a positive potential is output and a second node at which a negative potential is output. The potential generating circuit also includes a first filter between the first node and a first terminal that removes noise and outputs a filtered positive potential at the first terminal. A first clamp circuit adjusts the level of the filtered positive potential. A second filter is between the second node and a second terminal to remove noise from the negative potential and output a filtered negative potential at the second terminal. A second clamp circuit adjusts the level of the filtered negative potential. In the potential generating circuit there is no direct connection between the first end node and a ground line or between the ground line and the second end node.

### CROSS-REFERENCE TO RELATED APPLICATION

This application is based upon and claims the benefit of priority from Japanese Patent Application No. 2014-128594, filed Jun. 23, 2014, the entire contents of which are incorporated herein by reference.

### FIELD

Embodiments described herein relate generally to a positive and negative potential generating circuit.

### BACKGROUND

In a high frequency circuit unit of mobile terminal such as a mobile phone or smart phone, a transmitting circuit and a receiving circuit are configured so as to be selectively connected to a common antenna via a switch circuit for a high frequency signal (hereinafter, referred to as a high frequency switch circuit). In the related art, a high electron mobility transistor (HEMT) using a compound semiconductor is used for a switching element of the high frequency switching circuit, but according to demand for low price and miniaturization in recent years, replacing the compound semiconductor element with a metal oxide semiconductor field effect transistor (MOSFET) formed on a silicon substrate has been studied.

However, there is a problem that there is a great power loss of a high frequency signal because parasitic capacitance is large between a source electrode or a drain electrode and the silicon substrate, and silicon is employed as the semiconductor material. Therefore, a technology of forming a high frequency switching circuit on a silicon-on-insulator (SOI) substrate is proposed.

A turn-on potential of a high frequency switch is a gate potential at which on-resistance is small enough for a MOSFET in a high frequency switch in a conducting state. In addition, a turn-off potential is a gate potential at which a sufficient blocking (non-conducting) state may be maintained by the MOSFET, even if high frequency signals are superimposed across the source/drain terminals.

If the turn-on potential is lower than a desired potential (for example, 3 V), the on-resistance of an FET in a high frequency switch becomes larger, and insertion loss and on-distortion are increased. In addition, if the turn-off potential is higher than a desired potential (for example, −2 V), a maximum allowable input power is decreased, and thereby, off-distortion is increased.

In this way, when the gate potential of a high frequency switch is not set to an optimal potential at the time of turning on and at the time of turning off, electrical characteristics of the high frequency switch are degraded. Due to such circumstances, a power supply circuit for setting a gate potential of a high frequency switch to a desired potential is required.

In general, a power supply circuit generates a desired potential using a charge pump. Since a charge pump performs a boost operation or step-down operation of a voltage in synchronization with a clock signal, periodic harmonic noise on a ground line is superimposed.

For this reason, if a high frequency switch and a power supply circuit are formed on an SOI substrate, harmonic noise on a ground line of a power supply circuit is also mixed to the ground line of the high frequency switch, the harmonic noise is also superimposed to a harmonic signal which is switched by the high frequency switch, and there is a possibility that abnormality such as reduction of reception sensitivity or the like occurs.

### DESCRIPTION OF THE DRAWINGS

FIG. 1 is a block diagram illustrating a schematic configuration of a high frequency switching circuit which includes a positive and negative potential generating circuit according to a first embodiment.

FIG. 2 is a circuit diagram illustrating an internal configuration of a positive and negative potential generating circuit according to the first embodiment.

FIG. 3 is a circuit diagram of a charge pump according to a comparison example.

FIG. 4 is a diagram for explaining the charge pump of FIG. 3.

FIG. 5 is a circuit diagram illustrating an example of an internal configuration of a level shifter.

FIG. 6 is a circuit diagram illustrating an internal configuration of a positive and negative potential generating circuit according to a second embodiment.

FIG. 7 is a circuit diagram illustrating an internal configuration of a positive and negative potential generating circuit according to a third embodiment.

### DETAILED DESCRIPTION

Exemplary embodiments provide a positive and negative potential generating circuit in which harmonic noise is not superimposed to a ground line when a positive potential and a negative potential are generated.

In general, according to one embodiment, a potential generating circuit includes a charge pump having a first end node at which a positive potential is output and a second end node at which a negative potential is output. A first filter is connected between the first end node and a first terminal and configured to remove noise (such as high frequency harmonic noise) from the positive potential output from the first node end. The first filter outputs a filtered positive potential at the first terminal. For example, the first filter may remove high frequency noise. A first clamp circuit is configured to adjust a potential level of the filtered positive potential at the first terminal. The potential level set by the first clamp circuit may correspond to a level required for required for operation of a high frequency signal switching circuit. A second filter is connected between the second end node and a second terminal. The second filter is configured to remove noise (for example, high frequency harmonic noise) from the negative potential. The second filter outputs a filtered negative potential at the second terminal. For example, the second filter may remove high frequency noise. A second clamp circuit is configured to adjust a potential level of the filtered negative potential at the second terminal. The potential level set by the second clamp circuit may correspond to a level required for operation of a high frequency signal switching circuit. In the potential generating circuit, there is no direct connection between the first end node and a ground line and no direct connection between the ground line and the second end node. In this context, a “direct” connection means a current pathway that does not pass through a circuit element such as a capacitor, transistor, switch, or the like.

In general, according to one embodiment, a positive and negative potential generating circuit includes: a charge pump that includes one end side from which a positive potential is output, and the other end side from which a negative potential is output; a first filter that removes harmonic noise contained in the positive potential; a first clamp circuit that adjusts an output potential of the first filter; a second filter that removes harmonic noise contained in the negative potential; and a second clamp circuit that adjusts an output potential of the second filter, in which the charge pump makes the whole current that is output from the one end side flow into the first filter, and makes the whole current that has passed through the second filter from the second clamp circuit flow into the other end side.

Hereinafter, embodiments will be described with reference to the drawings. In the following embodiments, description is made for example configurations and operations of a positive and negative potential generating circuit are described, but these described examples are not limitations and other configurations and operations not specifically described will be apparent to those of ordinary skill in the art and these configurations and operations are within the scope of the present disclosure.

### First Embodiment

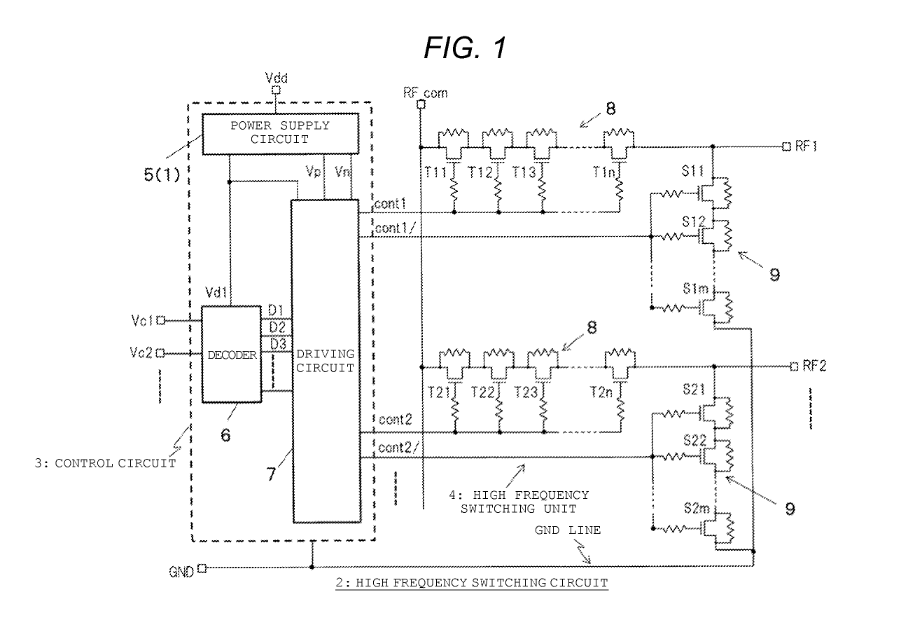

FIG. 1 is a block diagram illustrating a schematic configuration of a high frequency switching circuit 2 which includes a positive and negative potential generating circuit according to a first embodiment. The high frequency switching circuit 2 of FIG. 1 includes a control circuit 3, and a high frequency switching unit 4. In the first embodiment the entire high frequency switching circuit 2 of FIG. 1 is formed on a single semiconductor substrate (for example, a SOI substrate). As a result, the high frequency switching circuit 2 may be made as one chip, and is thus easily embedded in an electronic apparatus, such as a mobile phone, with reduced size and weight.

The control circuit 3 includes a power supply circuit 5, a decoder 6, and a driving circuit 7. The power supply circuit 5 generates a positive potential Vp and a negative potential Vn using a power supply potential Vdd. As will be described later, the positive and negative potential generating circuit 1 is provided in the power supply circuit 5. The decoder 6 decodes switching control signals Vc1, Vc2, and the like, which are input from outside of the high frequency switching circuit 2, and generates decoded signals D1, D2, D3, and the like. Based on the decoded signals (e.g., D1, D2, D3 . . . ), the driving circuit 7 generates switching control signals cont1, cont1/, cont2, cont2/, and the like for switching and controlling the high frequency switching unit 4.

The high frequency switching unit 4 includes a group of through FETs 8 and a group of shunt FETs 9. The group of through FETs 8 and the group of shunt FETs 9 each respectively have a plurality of MOSFETs which are connected in series to each other and use in common a gate potential (the gates of each respective group are commonly connected). Each group of through FETs 8 has a first end connected to a common signal node RF_com and a second end connected to a corresponding one of a high frequency signal nodes RF1, RF2, and the like, respectively. The common signal node RF_com is connected to, for example, an antenna (not specifically illustrated).

The shunt FETs 9 are connected between a corresponding one of the high frequency signal nodes RF1, RF2, and the like, and a ground potential (e.g., ground potential line “GND line”).

In the example of FIG. 1, a group of through FETs 8 and a group of shunt FETs 9 are provided for each high frequency signal node RF1, RF2, etc. The group of shunt FETs 9 and the complementarily group of through FETs 8 which correspond to one high frequency signal node, operate according to a switching control signal from the driving circuit 7. That is, when the group of through FETs 8 connected to the high frequency signal node RF1 turns on, the group of shunt FETs 9 connected between high frequency signal node RF1 and the GND line turns off. At this time, the groups of through FETs 8 and the groups of shunt FETs 9 connected to the other high frequency signal nodes RF2, RF3, etc. turn off and turn on, respectively. That is, each group through FETs 8 connected to a high frequency signal node other than RF1 turn off (become non-conducting) and each group of shunt FETs 9 connected to a high frequency signal node other than RF1 turn on (become conducting). As a result, by the switching control signals from the driving circuit 7, any one of the high frequency signal nodes may be electrically connected to the common signal node RF_com according to control signals supplied by the driving circuit 7.

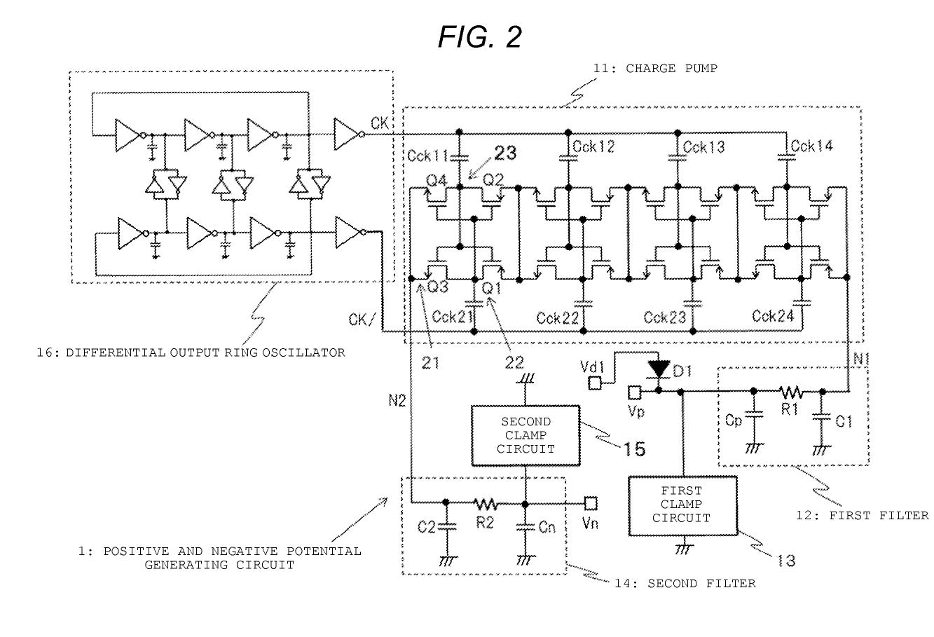

FIG. 2 is a circuit diagram illustrating an internal configuration of the positive and negative potential generating circuit 1 according to the first embodiment. The positive and negative potential generating circuit 1 of FIG. 2 includes a charge pump 11, a first filter 12, a first clamp circuit 13, a second filter 14, and a second clamp circuit 15. A differential clock signal (CK and CK/) is supplied to the positive and negative potential generating circuit 1 from a differential output ring oscillator 16.

The differential output ring oscillator 16 outputs differential clock signals (CK and CK/), the phases of which are inverted with respect to each other. In this disclosure, one clock signal of the differential clock signals is referred to as a first clock signal CK, and the other clock signal of the differential clock signals is referred to as a second clock signal CK/.

The charge pump 11 outputs a positive potential from one end side (node N1) and outputs a negative potential from the other end side (node N2), in synchronization with the differential clock signals.

The first filter 12 is a low pass filter which removes a high frequency noise (e.g., high-multiple harmonic noise) included in the positive potential output from the node N1. The first clamp circuit 13 adjusts an output potential level of the first filter 12 to be a desired level for operation of the driving circuit 7.

The second filter 14 is a low pass filter which removes a high frequency noise (e.g., high-multiple harmonic noise) included in the negative potential output from the node N2. The second clamp circuit 15 adjusts an output potential level of the second filter 14 to be a desired level for operation of the driving circuit 7.

In more detail, the charge pump 11 of FIG. 2 is a cross-coupled charge pump 11 which includes a plurality of CMOS pairs connected in series, a plurality of first capacitors Cck11 to Cck14, and a plurality of second capacitors Cck21 to Cck24.

The plurality of CMOS pairs 21 are connected in series between node N1 and node N2.

Each CMOS pair 21 includes a first CMOS circuit 22 (e.g., Q1 and Q3) and a second CMOS circuit 23 (e.g., Q2 and Q4) which are connected in parallel. A gate of the first CMOS circuit 22 and a gate of the second CMOS circuit 23 are cross-connected. That is, a gate of the CMOS circuit on one side is connected to a drain of the CMOS circuit on the other side, and a gate of the CMOS circuit on the other side is connected to a drain of the CMOS circuit on one side. Each first CMOS circuit 22 is connected in series with each other first CMOS circuit 22 between the node 1 and the node 2. Each second CMOS circuit 23 is connected in series with each other second CMOS circuit 23 between the node 1 and the node 2. The series-connected first CMOS circuits 22 are connected in parallel with the series-connected second CMOS circuits 23 between the node 1 and node 2.

In more detail, each of the first CMOS circuit 22 includes an NMOS transistor Q1 and a PMOS transistor Q3. Each of the second CMOS circuit 23 includes an NMOS transistor Q2 and a PMOS transistor Q4. Sources of the two NMOS transistors Q1 and Q2 in each CMOS pair 21 are connected together, and sources of the two PMOS transistors Q3 and Q4 in each CMOS pair 21 are connected together.

Each of the first capacitors Cck11 to Cck14 has a first end connected to the gates of the first CMOS circuit 22 in the corresponding CMOS pair 21 and the drains of the corresponding second CMOS circuit 23, and a second end connected to a supplying node of the first clock signal CK.

Each of the second capacitors Cck21 to Cck24 has a first end connected to the gates of the second CMOS circuit 23 in the corresponding CMOS pair 21 and the drains of the corresponding second CMOS circuit 23, and a second end connected to a supplying node of the second clock signal CK/.

In synchronization with the differential clock signal, the charge pump 11 repeats charging and discharging according to the plurality of first capacitors Cck11 to Cck14 and the plurality of second capacitors Cck21 to Cck24. As a result, a positive potential Vp and a negative potential Vn are generated. The positive potential is output from the one end side node N1, and the negative potential is output from the other end side node N2.

Current output from the one end side node N1 flows into the first clamp circuit 13 via the first filter 12. In addition, current which passes through the second filter 14 from the second clamp circuit 15 flows into the other end side node N2.

As illustrated in FIG. 2, the one end side node N1 is connected to an input node of the first filter 12, the other end side node N2 is connected to an input node of the second filter 14, both the node N1 and node N2 are not directly connected to a ground line. That is, at least one circuit element is between the node N1/N2 and a ground line (or ground potential).

In addition, the plurality of CMOS pairs 21, the plurality of the first capacitors Cck11 to Cck14, and the plurality of the second capacitors Cck21 to Cck24 included in the charge pump 11, are not directly connected to the ground line. In this way, since the charge pump 11 is not connected to the ground line, there exists no current path through which harmonic noise created while the charge pump 11 performs a charge pump operation in synchronization with the differential clock signal flows into the ground line.

The first filter 12 is a low pass filter which removes harmonic noise included in the positive potential output from the node N1 of the charge pump 11. For example, the first filter 12 includes a capacitor C1 which is connected between the node N1 and the ground line, an impedance element R1 which is connected between the node N1 and a node of the positive potential Vp, and a capacitor Cp which is connected between the node of the positive potential Vp and the ground line.

The second filter 14 is a low pass filter which removes harmonic noise included in the negative potential output from the node N2 of the charge pump 11. For example, the second filter 14 includes a capacitor C2 which is connected between the node N2 and the ground line, an impedance element R2 which is connected between the node N2 and a node of the negative potential Vn, and a capacitor Cn which is connected between the node of the negative potential Vn and the ground line.

Since the capacitance of the capacitors in the first filter 12 and the capacitance of the capacitors in the second filter 14 decrease the internal impedance of the positive and negative potential generating circuit 1 when viewed from the node side of the positive potential Vp and the node side of the negative potential Vn, the capacitance of the capacitors in the first filter 12 and the capacitance of the capacitors in the second filter 14 are set to a large value of several hundred pF.

The first clamp circuit 13 is connected between the node of positive potential Vp and the ground line. The first clamp circuit 13 is a circuit for setting a potential level of the node of the positive potential Vp, and for example, may include plurality of diodes connected in series.

In addition, a pull-up diode D1 is connected between a power supply potential node Vd1 and the node of the positive potential Vp. The diode D1 is optionally present in some embodiments, but it nearly instantaneously increases a potential level of the node of the positive potential Vp up to a level close to the power supply potential node Vd1, when the power of the positive and negative potential generating circuit 1 is supplied. By providing the diode D1, it is possible to reduce the time which is taken until the positive potential Vp reaches a desired potential.

Next, an operation of the positive and negative potential generating circuit 1 of FIG. 2 will be described. If a power supply potential is supplied to the positive and negative potential generating circuit 1, the differential output ring oscillator 16 starts an oscillation operation, and generates a differential clock signal including the first clock signal CK and the second clock signal CK/, phases of which are inverted with respect to each other.

If the differential clock signal is input to each of the plurality of first capacitors Cck11 to Cck14 and the plurality of second capacitors Cck21 to Cck24, the charge pump 11 repeats charging and discharging, and according to this, the positive potential is output from the node N1, and the negative potential is output from the node N2. The greater the number of connected stages in the plurality of CMOS pairs 21 in the charge pump 11, the larger an absolute value of the positive potential and the negative potential is. In addition, the larger a voltage amplitude of the differential clock signal is, the larger the absolute value of the positive potential and the negative potential is. The voltage amplitude of the differential clock signal is dependent on a power supply potential supplied to the differential output ring oscillator 16. Thus, if the power supply potential is constant, the number of connected stages in the plurality of CMOS pairs 21 in the charge pump 11 may be adjusted, whereby, it is possible to variably control the value of the positive potential and the negative potential.

For example, when the ground level is 0 V, the absolute value of the positive potential and the absolute value of the negative potential are the same, if the number of connected stages of the plurality of CMOS pairs 21 in the charge pump 11 is 2n stages (where n is an integer of one or more), a node between the CMOS pair 21 of the nth stage and the CMOS pair 21 of the (n+1)th stage, when counting from the node N1, becomes a midpoint of 0 V. If the absolute value of the positive potential and the absolute value of the negative potential are different from each other, a position of the midpoint is shifted to a place other than the position between the CMOS pair 21 of the nth stage and the CMOS pair 21 of the (n+1)th stage.

The harmonic noise included in the positive potential Vp which is output from the node N1 of the charge pump 11 is removed by the first filter 12. Thus, positive potential without harmonic noise is supplied to the node of the positive potential Vp.

In the same manner as this, the harmonic noise included in the negative potential which is output from node N2 of the charge pump 11 is removed by the second filter 14. Thus, negative potential Vn without harmonic noise is supplied to the node of the negative potential Vn.

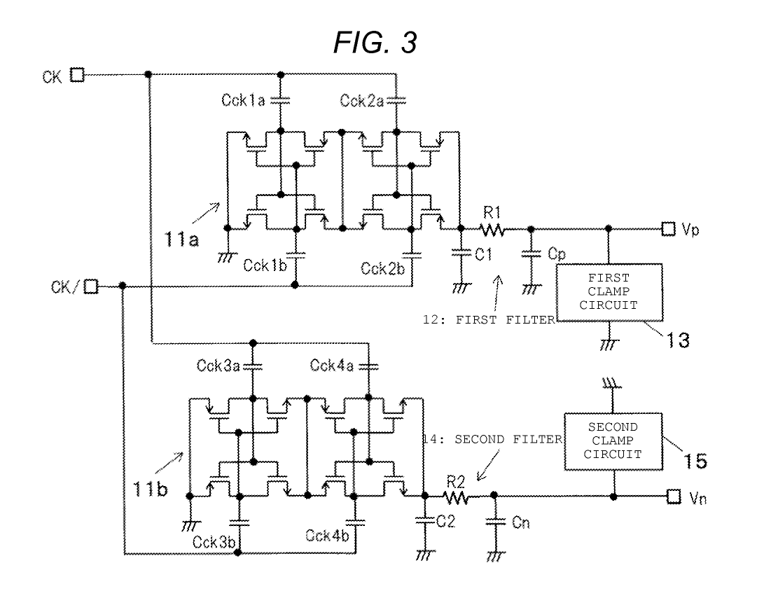

FIG. 3 is a circuit diagram of the charge pump 11 according to a comparison example. The charge pump 11 of FIG. 3 includes a first charge pump unit 11a which generates a positive voltage, and a second charge pump unit 11b which generates a negative voltage. The charge pump 11 depicted in FIG. 3 also includes first filter 12, second filter 14, first clamp circuit 13, and second clamp circuit 15.

The first charge pump unit 11a and the second charge pump 11b each have the same general internal configurations as charge pump 11 of FIG. 2, and thus include a plurality of CMOS pairs 21, which are connected in series to each other, a plurality of first capacitors Cck1a and Cck2a, or Cck3a and Cck4a, and a plurality of second capacitors Cck1b and Cck2b, or Cck3b and Cck4b, respectively. However, an end of the plurality of CMOS pairs 21 of FIG. 3 in charge pump units 11a and 11b is directly grounded. This is a crucial difference between the charge pump 11 of FIG. 2 and the charge pump units 11a and 11b.

In the charge pump according to the comparison example illustrated in FIG. 3, the harmonic noise created when the first charge pump unit 11a and the second charge pump unit 11b perform a charge pump operation in synchronization with the differential clock signal is superimposed on the ground line.

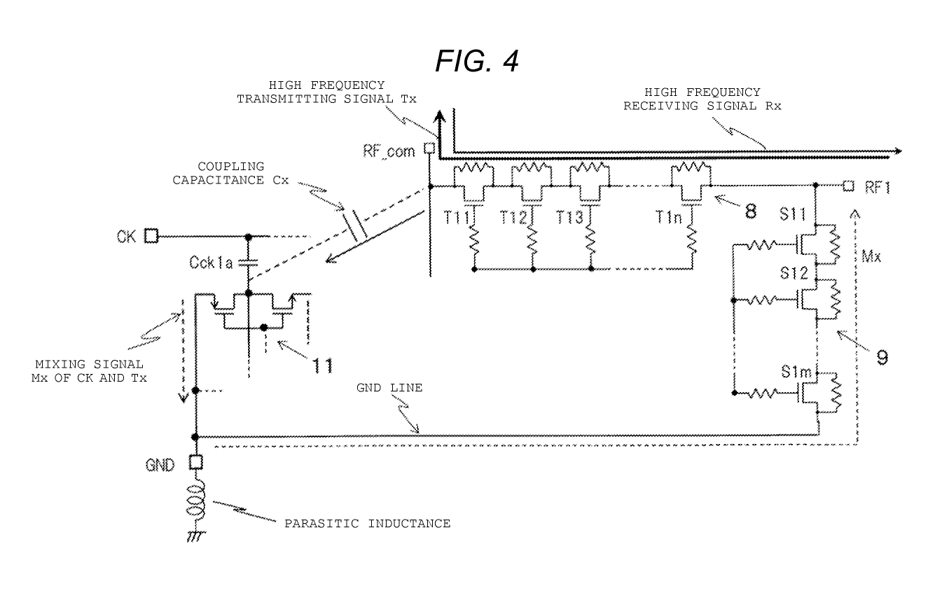

FIG. 4 is a diagram illustrating operation of the charge pump 11 of FIG. 3. The power supply circuit 5, in which the charge pump 11 is embedded, and the high frequency switching unit 4 are on one semiconductor substrate (for example, SOI substrate), and thus, a coupling capacitance Cx exists between the charge pump 11 and the high frequency switching unit 4, as illustrated in FIG. 4. The coupling capacitance Cx is a relatively small capacitance of approximately several fF (femtofarad), for example, but the following problem occurs.

A high frequency transmitting signal Tx, switching control of which is performed by the high frequency switching unit 4, is capacitance-coupled with the charge pump 11 by the coupling capacitance Cx. Since differential clock signals CK and CK/ are supplied to the charge pump 11, and the charge pump is a non-linear circuit, mixing occurs between the differential clock signals CK and CK/ and the high frequency signal Tx.

Here, it is assumed that the frequencies of the differential clock signals CK and CK/ are approximately 10 MHz. In general, the clock signal is a rectangular wave and has harmonic components of an extremely high order. In addition, harmonic components of a high order are also produced by mixing of the differential clock signals CK and CK/ and the high frequency transmitting signal Tx. For example, noise is created by a frequency sum of a harmonic wave of the nineteenth order of the differential clock signals CK and CK/, and the high frequency transmitting signal Tx. A frequency of the noise in this case is represented by the following Formula (1).

1950 MHz+10 MHz×19=2140 MHz (1)

A signal which is represented by Formula (1) is referred to as a noise signal Mx.

The noise signal Mx is superimposed to the ground line of the charge pump 11. The reason is that a parasitic inductance exists between a ground line in a semiconductor chip and an ideal ground line, the ground line in the semiconductor chip is in a state of electrical floating at a high frequency region, and a noise signal which flows through the ground line of the charge pump 11 remains on the ground line without attenuation. Thus, the noise signal also flows into the ground line of the high frequency switching unit 4. A group of shunt FETs 9 in the high frequency switching unit 4 becomes off-capacitances between the ground lines in an off state. Thus, if the noise signal is superimposed to the ground line, the noise signal is also superimposed to the high frequency signal node connected to the group of shunt FETs 9. As represented by Formula (1), the noise signal Mx is the frequency of a receiving signal, and thus, noise is mixed into a high frequency receiving signal band, thereby causing a decrease of reception sensitivity.

In this way, the charge pump 11 according to the comparison example illustrated in FIG. 3 has a current path which is connected to the ground line, and thus, the harmonic noise which is created by the charge pump operation flows into the ground line, and negative effect on the reception band of the high frequency switching unit 4, which is connected to the same ground line, results.

In contrast to this, the charge pump 11 according to the first embodiment does not have a current path which is connected to the ground line, and thus, the harmonic noise which is created by the charge pump operation does not flow into the ground line.

In addition, in the positive and negative potential generating circuit 1 according to the first embodiment, the charge pump 11 itself is not directly connected to the ground line, but rather the first filter 12, which is connected to node N1 of the charge pump 11, and the second filter 14, which is connected to node N2, are connected to the ground line. The instantaneous harmonic noise which is created by the charge pump 11 is thus absorbed/removed by the first filter 12 and the second filter 14, and the harmonic noise flowing through the ground lines of the first filter 12 and the second filter 14 is substantially reduced.

The positive potential and the negative potential which are generated by the positive and negative potential generating circuit 1 is supplied to the driving circuit 7, as illustrated in FIG. 1. The driving circuit 7 includes level shifter 25 inside. The level shifter 25 converts a potential level of the decoded signal D1 or the like, and generates a switching control signal con1 or the like for performing switching control of the high frequency switching unit 4.

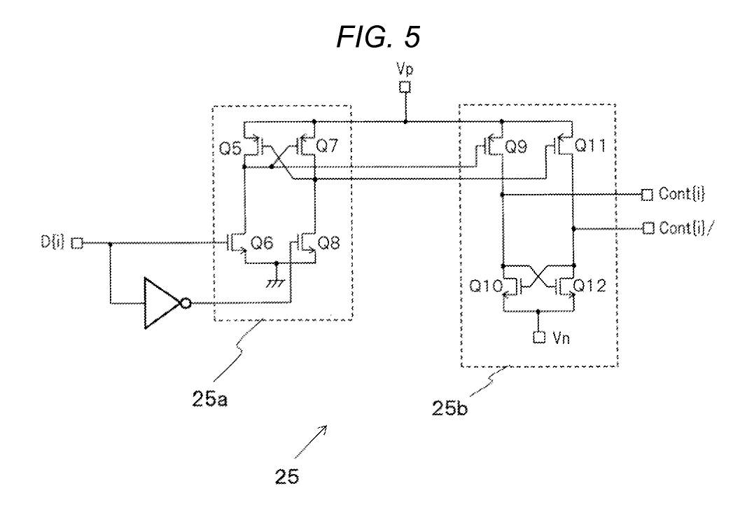

FIG. 5 is a circuit diagram illustrating an example of the level shifter 25. The level shifter 25 in FIG. 5 includes a front stage level shifter unit 25a and a rear stage level shifter unit 25b.

The front stage level shifter unit 25a includes a PMOS transistor Q5 and an NMOS transistor Q6 which are connected in series between a positive potential Vp and a ground line. The front stage level shifter unit 25a also includes a PMOS transistor Q7 and an NMOS transistor Q8 which are connected in series between the same positive potential Vp and the ground line. One decoding signal D[i] is input to a gate of the NMOS transistor Q6, and an inverted signal of the decoding signal D[i] is input to a gate of the NMOS transistor Q8. The PMOS transistors Q5 and Q7 are cross-connected. That is, a gate of the PMOS transistor Q5 is connected to a connection node of the transistors Q7 and Q8, and a gate of the PMOS transistor Q7 is connected to a connection node of the transistors Q5 and Q6.

The rear stage level shifter unit 25b includes a PMOS transistor Q9 and an NMOS transistor Q10 which are connected in series between a positive potential Vp and a negative potential Vn, The rear stage level shifter unit 25b also includes a PMOS transistor Q11 and an NMOS transistor Q12 which are connected in series between the same positive potential Vp and the same negative potential Vn.

The NMOS transistors Q10 and Q12 are cross-connected. A gate of the PMOS transistor Q9 is connected to a connection node of the transistors Q5 and Q6, and a signal Cont[i] in which a potential level is converted is output from this connection node. A gate of the PMOS transistor Q11 is connected to a connection node of the transistors Q7 and Q8, and an inverted signal cont[i]/of the signal Cont[i] in which a potential level is converted is output from this connection node.

In this way, since there is no current path which is directly connected to the ground line in the charge pump 11 according to the first embodiment, the harmonic noise which is created by an instantaneous current change occurring due to the charge pump operation does not flow into the ground line. Thus, the harmonic noise which is created by the charge pump operation is not superimposed on a receiving signal band in which the high frequency switching unit 4, which may use a common ground line, performs a switching control, thereby improving the receiving characteristic.

### Second Embodiment

In a second embodiment w, an internal circuit configuration of a charge pump 11 is different from that of the first embodiment.

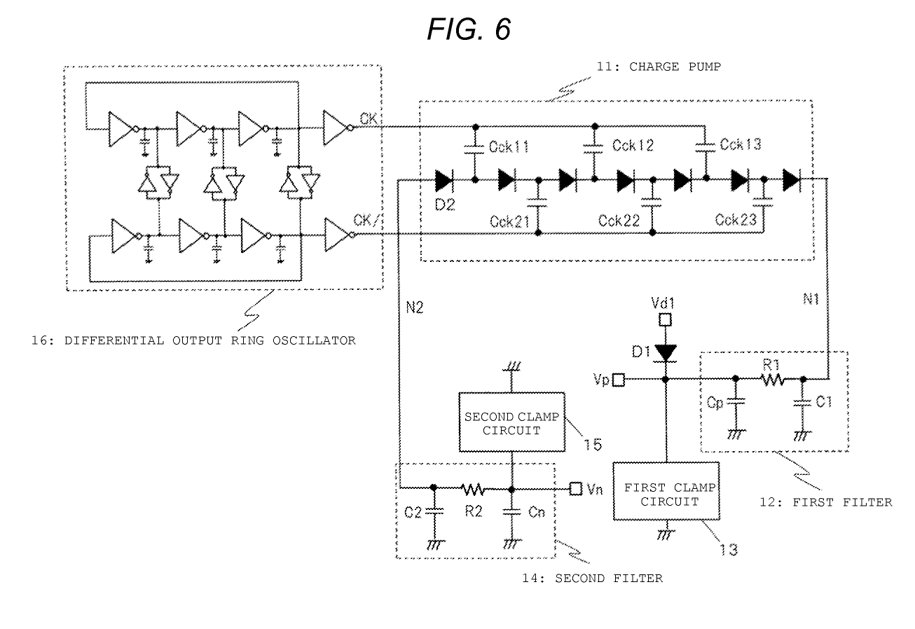

FIG. 6 is a circuit diagram illustrating an internal configuration of a positive and negative potential generating circuit 1 according to the second embodiment. The positive and negative potential generating circuit 1 of FIG. 6 is similar to that of FIG. 2 other than specifically the internal configuration of the charge pump 11 is different from that of FIG. 2.

The charge pump 11 of FIG. 6 includes a plurality of diodes which are connected in series to each other in a forward direction (cathode-to-anode), a plurality of first capacitors Cck11 to Cck14 which are connected between adjacent diodes (e.g., between n and n+1 diodes) and to a supplying node of a first clock signal CK, and a plurality of second capacitors Cck21 to Cck24 are connected between adjacent diodes (e.g., n+1 and n+2 diodes) and to a supplying node of a second clock signal CK/. The first capacitors Cck11 to Cck14 and the second capacitors Cck21 to Cck24 alternate connection points between the diodes. That is, in an example, a first capacitor Cck11 is connected between a first and a second diode in the series of diodes, then a second capacitor Cck21 is connected between the second diode and a third diode in the series of diodes. The connection points for the first and second capacitors alternate along the series of diodes as, for example, as depicted in FIG. 6.

In this way, the charge pump 11 of FIG. 6 is a so-called Dixon-type charge pump. Each diode of the charge pump 11 is a pn junction diode which is formed on, for example, an SOI substrate. By forming a pn junction diode on an SOI substrate, a pn junction diode without a well may be formed.

Even in the charge pump 11 of FIG. 6, in synchronization with a differential clock signal, the first capacitors Cck11 to Cck14 and the second capacitors Cck21 to Cck24 repeat charging and discharging, and according to this, the charge pump 11 outputs a positive potential from node N1, and outputs a negative potential from node N2. Potential levels of the positive potential and the negative potential are dependent on a voltage amplitude of the differential clock signal and the number of c diodes connected in series in the charge pump 11.

A cathode of the diode connected to node N1 of the charge pump 11 is directly connected to an input node of a first filter 12. In addition, an anode of the diode connected to node N2 of the charge pump 11 is directly connected to an input node of a second filter 14.

In the charge pump 11 of FIG. 6, there exists no current path which is connected to a ground line, and node N1 and node N2 which are connected the charge pump 11 are also not connected to the ground line. Thus, in the same manner as the first embodiment, an instantaneous harmonic noise which is created by the charge pump operation does not flow into the ground line.

In this way, in the second embodiment, there is also no current path which is connected to the ground line of the charge pump 11, thus the harmonic noise which is created by an instantaneous current change occurring due to the charge pump operation does not flow/propagate into the ground line.

### Third Embodiment

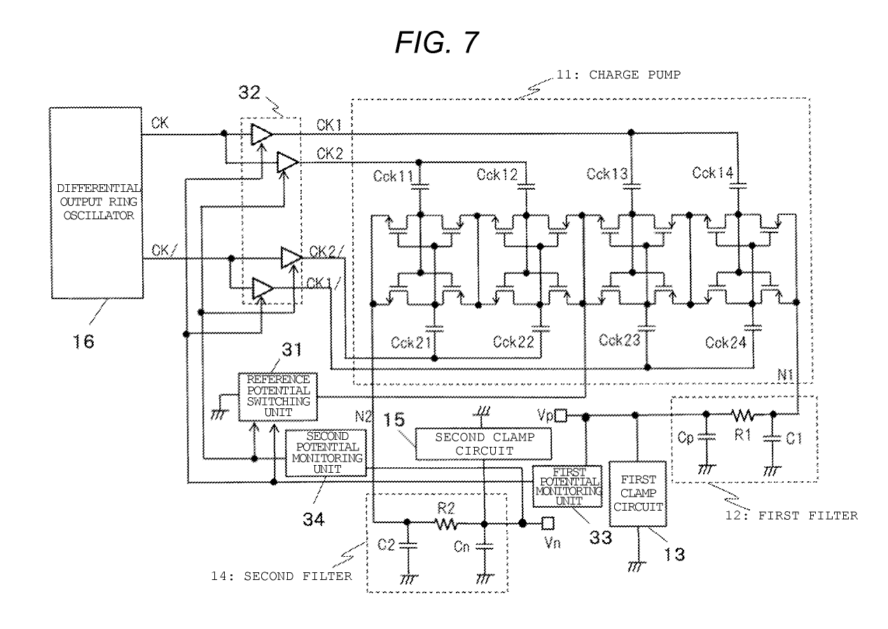

FIG. 7 is a circuit diagram illustrating an internal configuration of a positive and negative potential generating circuit 1 according to a third embodiment. The positive and negative potential generating circuit 1 of FIG. 7 has substantially the same internal configuration of a charge pump 11 as that depicted in FIG. 2, but includes a reference potential switching unit 31 that switches a potential of a reference node in the charge pump 11 to a predetermined reference node potential, a buffer circuit 32 which varies the driving capability of a differential clock signal, a first potential monitoring unit 33, and a second potential monitoring unit 34.

The reference node which is switched by the reference potential switching unit 31 is disposed at a midpoint of the charge pump 11—that is, the reference node is between a first half of the CMOS pairs 21 (see FIG. 2) and a second half of the CMOS pairs 21 (see FIG. 2). If an absolute value of the positive potential Vp is equal to an absolute value of the negative potential Vn, the midpoint is ideally set so as to be a ground level. However, if large load variation occurs in the driving circuit 7 or the like which uses the positive potential Vp and the negative potential Vn which are generated by the positive and negative potential generating circuit 1, a potential level of the midpoint temporarily varies. If the potential level of the midpoint varies, the potential levels of the positive potential Vp and the negative potential Vn are also varied, and thus, the charge pump 11 performs control to return the positive potential Vp and the negative potential Vn to an ideal potential. However, if an amount of load variation is large, there is a possibility that it takes time until returning to the ideal positive potential Vp and the ideal negative potential Vn. Thus, if the load variation occurs, the reference potential switching unit 31 operates in such a manner that the charge pump 11 rapidly outputs the ideal positive potential Vp and the ideal negative potential Vn, by forcibly setting the midpoint to the reference potential (for example, ground level).

The reference potential switching unit 31 is configured to determine whether or not load variation has occurred using signals from the first potential monitoring unit 33 and the second potential monitoring unit 34. The first potential monitoring unit 33 monitors an output potential of the first filter 12, that is, the positive potential Vp (at the node Vp). If the positive potential Vp does not reach a predetermined potential level prior to reaching a desired potential level, the first potential monitoring unit 33 outputs a signal indicating that variation has occurred. The second potential monitoring unit 34 monitors an output potential of the second filter 14, that is, the negative potential Vn (at the node Vn, and if the negative potential Vn does not reach a predetermined potential level prior to reaching a desired potential level, outputs a signal indicating that variation has occurred.

When at least one of the positive potential Vp and the negative potential Vn is lower than the predetermined potential level, as detected by either the first potential monitoring unit 33 or the second potential monitoring unit 34, the reference potential switching unit 31 forcibly sets the reference node in the charge pump 11 to a reference potential. This operation of setting the reference node to the reference potential is called an on-operation of the reference potential switching unit 31, and an operation of not setting the reference node to the reference potential is called an off-operation.

The buffer circuit 32 adjusts a driving capability of a differential clock signal which is output from the differential output ring oscillator 16 and supplies the adjusted signal to the charge pump 11. More specifically, while the positive potential Vp and the negative potential Vn which are generated by the charge pump 11 do not reach the desired potential levels, the buffer circuit 32 increases the driving capability of the differential clock signal. That is, an output impedance from the buffer circuit 32 is increased. As a result, the charge pump 11 may increase the absolute values of the positive potential Vp and the negative potential Vn in a shorter time, and it is possible to speed up the charge pump operation of the charge pump 11.

In addition, if the positive potential Vp and the negative potential Vn generated by the charge pump 11 reaches or exceeds the desired potential level, the buffer circuit 32 decreases the driving capability of the differential clock signal. That is, the output impedance of the buffer circuit 32] is increased. As a result, the charge pump 11 maintains the potential levels of the positive potential Vp and the negative potential Vn in a more stable manner. Thus, it is possible to control the instantaneous current which flows through the charge pump 11, in synchronization with the differential clock signal, and noise immunity performance is enhanced. In addition, according to the decreased driving capability of the differential clock signal, power consumption is decreased.

Based on the signals from the first potential monitoring unit 33 and the second potential monitoring unit 34, the buffer circuit 32 determines whether or not at least one of the positive potential Vp and the negative potential Vn reaches the predetermined potential level. If at least one of the positive potential Vp and the negative potential Vn does not reach the predetermined potential levels, the buffer circuit 32 performs an operation of increasing the driving capability of the differential clock signal, and if at least one of the positive potential Vp and the negative potential Vn reaches the predetermined potential level, the buffer circuit 32 performs an operation of decreasing the driving capability of the differential clock signal.

In addition, the buffer circuit 32 may adjust the driving capability of the differential clock signal gradually or continuously. In this case, by the first potential monitoring unit 33 and the second potential monitoring unit 34, a difference between the measured value and the desired target value of the positive potential Vp is detected, a difference between the measured value and the target value of the negative potential Vn is also detected, and based on the differences, the buffer circuit 32 may adjust the driving capability of the differential clock signal gradually or continuously.

In addition, in some embodiments, there is no need to provide both of the reference potential switching unit 31 and the buffer circuit 32 within the positive and negative potential generating circuit 1, and either of the reference potential switching unit 31 and the buffer circuit 32 may be provided within the positive and negative potential generating circuit 1 rather than both. In addition, if both of the reference potential switching unit 31 and the buffer circuit 32 are provided within the positive and negative potential generating circuit 1, it is preferable that the reference potential switching unit 31 and the buffer circuit 32 be operated in conjunction with each other. That is, if at least one of the positive potential Vp and the negative potential Vn does not reach the predetermined potential level from a desired potential, it is preferable that by activating the reference potential switching unit 31, the reference node in the charge pump 11 be set to the reference potential, and by the buffer circuit 32, the driving capability of the differential clock signal be increased. In addition, if at least one of the positive potential Vp and the negative potential Vn reaches the predetermined potential level which is assumed in advance, it is preferable that the reference potential switching unit 31 be deactivated, and by the buffer circuit 32, the driving capability of the differential clock signal be decreased.

In this way, in the third embodiment, the reference potential switching unit 31, which switches whether or not the reference node in the charge pump 11 is set to the reference potential, is provided, and thus, if the potential level of at least one of the positive potential Vp and the negative potential Vn varies, it is possible to speedup the charge pump operation by forcibly setting the reference node to the reference potential, and even if there is load variation, it is possible to rapidly return the positive potential Vp and the negative potential Vn to a desired potential.

In addition, in the third embodiment, the buffer circuit 32 may switch the driving capability of the differential clock signal. As such, the driving capability of the differential clock signal is increased until the positive potential Vp and the negative potential Vn reach a desired potential, it is possible to speed up the charge pump operation, and it is possible to rapidly set the positive potential Vp and the negative potential Vn to a desired potential level.

In FIG. 7, an internal configuration of the charge pump 11 is substantially the same as that of FIG. 2, but can be the same as that of FIG. 6 in other embodiments. In addition, a diode for pull-up which is substantially the same as that of FIG. 6 (e.g., diode D1) may also be connected to the node of the positive potential Vp of FIG. 7.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A potential generating circuit, comprising:
a charge pump having a first end node at which a positive potential is output and a second end node at which a negative potential is output;
a first filter between the first end node and a first terminal and configured to remove harmonic noise from the positive potential and output a filtered positive potential at the first terminal;
a first clamp circuit configured to adjust a potential level of the filtered positive potential at the first terminal;
a second filter between the second end node and a second terminal and configured to remove harmonic noise from the negative potential and output a filtered negative potential at the second terminal; and
a second clamp circuit configured to adjust a potential level of the filtered negative potential at the second terminal, wherein
there is no direct connection between the first end node and a ground line and no direct connection between the ground line and the second end node.

2. The potential generating circuit according to claim 1, wherein the charge pump includes:
a plurality of CMOS pairs connected in series between the first end node and the second end node, each CMOS pair having a first CMOS circuit and a second CMOS circuit connected in parallel with each other, each first CMOS circuit and second CMOS circuit in each CMOS pair having:
a first capacitor with a first capacitor end connected both to a gate of the first CMOS circuit and to a drain of the second CMOS circuit and a second capacitor end connected a first clock signal node; and
a second capacitor having a third capacitor end connected both to a gate of the second CMOS circuit and to a drain of the first CMOS circuit and a fourth capacitor end connected to a second clock signal node,
wherein a first clock signal is supplied at the first clock signal node and a second clock signal, having a phase which is inverted with respect to the first clock signal, is supplied at the second clock signal node.

3. The potential generating circuit according to claim 2, further comprising:
a first potential monitoring unit configured to monitor an output potential of the first filter and output a first monitoring result corresponding to the output potential of the first filter;
a second potential monitoring unit configured to monitor an output potential of the second filter and output a second monitor result corresponding to the output potential of the second filter; and
a reference potential switching unit configured to set a potential at a reference node that is between an adjacent pair of CMOS pairs to a reference potential according to the first and second monitoring results.

4. The potential generating circuit according to claim 3, wherein the number of CMOS pairs between the first end node and the reference node is equal to the number of CMOS pairs between the second end node and the reference node.

5. The potential generating circuit according to claim 1, the charge pump including:
a plurality of diodes connected in series in a forward direction between the second end node and the first end node;
a plurality of first capacitors each having a first capacitor end connected to a first clock signal node and a second capacitor end connected to a node between a first adjacent pair of diodes in the plurality of diodes; and
a plurality of second capacitors each having a third capacitor end connected to a second clock signal node and fourth capacitor end connected to a node between a second adjacent pair of diodes in the plurality of diode, wherein
first and second adjacent pairs of diodes in the plurality of diodes alternate with each other between the first end node end and the second end node, with a first adjacent pair of diodes being connected to the second node end and a second adjacent pair of diodes being connected to first node, and
a first clock signal is supplied at the first clock signal node and a second clock signal, having a phase which is inverted with respect to the first clock signal, is supplied at the second clock signal node.

6. The potential generating circuit according to claim 1, further comprising:
a first potential monitoring unit configured to monitor an output potential of the first filter and output a first monitoring result corresponding to the output potential of the first filter;
a second potential monitoring unit configured to monitor an output potential of the second filter and output a second monitor result corresponding to the output potential of the second filter; and
a reference potential switching unit configured to set a potential at a reference node in the charge pump to a reference potential according to the first and second monitoring results, the reference node being between the first and second end nodes.

7. The potential generating circuit according to claim 6, wherein the charge pump includes a plurality of diodes connected in series in a forward direction between the second end node and the first end node, and the reference node is between an adjacent pair of diodes in the plurality of diodes.

8. The potential generating circuit according to claim 6, wherein the reference potential switching unit is configured to maintain the reference node at the reference potential until the output potentials of the first and second filters respectively reach a predetermined potential.

9. The potential generating circuit according to claim 1, further comprising:
a first potential monitoring unit configured to monitor an output potential of the first filter and output a first monitoring result corresponding to the output potential of the first filter;
a second potential monitoring unit configured to monitor an output potential of the second filter and output a second monitor result corresponding to the output potential of the second filter; and
a driving capacity adjusting unit configured to adjust voltage amplitude of a differential clock signal supplied to the charge pump according to the first and second monitoring results.

10. The potential generating circuit according to claim 9, wherein the driving capability adjusting unit increases the voltage amplitude of the differential clock signal until each output potential of the first filter and the second filter reaches a predetermined potential, and decreases the voltage amplitude of the differential clock signal after each output potential of the first filter and the second filter reaches the predetermined potential.

11. The potential generating circuit according to claim 1, further comprising:
a first potential monitoring unit configured to monitor an output potential of the first filter and output a first monitoring result corresponding to the output potential of the first filter;
a second potential monitoring unit configured to monitor an output potential of the second filter and output a second monitor result corresponding to the output potential of the second filter;
a reference potential switching unit configured to set a potential at a reference node in the charge pump between the first end node and the second end node to a reference potential to a reference potential according to the first and second monitoring results; and
a driving capacity adjusting unit configured to adjusts a voltage amplitude of a differential clock signal supplied to the charge pump according to the first and second monitoring results, wherein
the driving capability adjusting unit increases the voltage amplitude of the differential clock signal until the output potential of the first filter and the output potential of the second filter reaches a predetermined potential level when the reference potential switching unit sets the reference node to the reference potential, and
the driving capability adjusting unit decreases the voltage amplitude of the differential clock signal when the output potential of the first filter and output potential of the second filter reaches the predetermined potential level and the reference potential switching unit stops setting the reference node to the reference potential.

12. A power supply circuit, comprising:
a charge pump including:
a first plurality of transistor pairs connected in series between a first end node and a second end node, each transistor pair in the first plurality including a NMOS-type transistor and a PMOS-type transistor coupled drain to drain and gate to gate;
a second plurality of transistor pairs connected in series between the first end node and the second end node and in parallel with the first plurality of transistors between the first end node and the second end node, each transistor pair in the second plurality including a NMOS-type transistor and a PMOS-type transistor coupled drain to drain and gate to gate;
a first plurality of capacitors having a first capacitor end connected to a node between drains of a transistor pair in first plurality of transistor pairs and a second capacitor end connected to a first clock signal input node;
a second plurality of capacitors having a first capacitor end respectively connected to a node between drains of a transistor pair in the second plurality of transistor pairs and a second capacitor end connected to a second clock signal input node, wherein
each NMOS-type transistor in the first plurality of transistor pairs has a source connected to a source of a corresponding one of the NMOS-type transistors in the second plurality of transistor pairs, and
each PMOS-type transistor in the first plurality of transistor pairs has a source connected to a source of a corresponding one of the PMOS-type transistors in the second plurality of transistor pairs;
a first filter between the first end node and a first terminal at which a positive potential is output; and
a second filter between the second end node and a second terminal at which a negative potential is output, wherein
there is no direct current path between the first end node and a ground line and no direct current path between the ground line and the second end node.

13. The power supply circuit according to claim 12, further comprising:
a first clamp circuit connected to the first terminal and configured to set the positive potential at the first terminal to a first predetermined level; and
a second clamp circuit connected to the second terminal and configured to set the negative potential at the second terminal to a second predetermined level.

14. The power supply circuit according to claim 12, further comprising:
a diode having a cathode connected to the first terminal and an anode connected to a power supply voltage terminal.

15. The power supply circuit according to claim 12, further comprising:
a differential output ring oscillator connected to the first and second clock signal input nodes and configured to output a first clock signal to the first clock signal input node and to output a second clock signal, having a phase inverted with respect to the first clock signal, to the second clock signal input node.

16. The power supply circuit according to claim 15, wherein the driving capability adjusting unit decreases the voltage amplitude of the differential clock signal when the output potential of the first filter and the output potential of the second filter reaches the predetermined potential level and the reference potential switching unit stops setting the reference node to the reference potential.

17. The power supply circuit according to claim 12, further comprising:
a first potential monitoring unit configured to monitor an output potential of the first filter and output a first monitoring result corresponding to the output potential of the first filter;
a second potential monitoring unit configured to monitor an output potential of the second filter and output a second monitor result corresponding to the output potential of the second filter;
a reference potential switching unit configured to set a potential of a reference node to a reference potential according to the first and second monitoring results, the reference node being connected to the source of a NMOS-type transistor in the first plurality of transistors; and
a driving capacity adjusting unit configured to adjust a voltage amplitude of a differential clock signal supplied to the charge pump according to the first and second monitoring results,
wherein the driving capability adjusting unit increases the voltage amplitude of the differential clock signal until the output potential of the first filter and the output potential of the second filter reaches a predetermined potential level when the reference potential switching unit sets the reference node to the reference potential.

18. A power supply circuit, comprising:
a charge pump including:
a plurality of diodes forward-connected in series between a first node and a second node, a first diode in the plurality having an anode connected to the second node and a cathode connected to an anode of a second diode in the plurality;
a plurality of first capacitors having a first capacitor end connected between every other adjacent pair of diodes connected in series, starting with the first and second diodes, and a second capacitor end connected to a first clock signal node;
a plurality of second capacitors having a first capacitor end connected between every other adjacent pair of diodes connected in series, starting with the second diode and a third diode in the plurality having an anode connected to a cathode of the second diode, and a second capacitor end connected to a second clock signal node;
a first filter between the first node and a first terminal at which a positive potential is output; and
a second filter between the second node and a second terminal at which a negative potential is output, wherein
there is no direct current path between the first node and a ground line and no direct current path between the ground line and the second node.

19. The power supply circuit according to claim 18, further comprising:
a first clamp circuit connected to the first terminal and configured to set the positive potential at the first terminal to a first predetermined level; and
a second clamp circuit connected to the second terminal and configured to set the negative potential at the second terminal to a second predetermined level.

20. The power supply circuit according to claim 18, further comprising:
a first potential monitoring unit configured to monitor an output potential of the first filter and output a first monitoring result corresponding to the output potential of the first filter;
a second potential monitoring unit configured to monitor an output potential of the second filter and output a second monitor result corresponding to the output potential of the second filter;
a reference potential switching unit configured to set a potential of a reference node to a reference potential according to the first and second monitoring results, the reference node being connected to the source of a NMOS-type transistor in the first plurality of transistors; and
a driving capacity adjusting unit configured to adjust a voltage amplitude of a differential clock signal supplied to the charge pump according to the first and second monitoring results, wherein
the driving capability adjusting unit increases a voltage amplitude of the differential clock signal until the output potential of the first filter and the output potential of the second filter reaches a predetermined potential level when the reference potential switching unit sets the reference node to the reference potential.
